(19) United States
(12) Patent Application Publication
(10) Pub. No.: US 2025/0010331 A1
(43) Pub. Date: Jan. 9, 2025

(54) ALKOXYSILANES AND DENSE ORGANOSILICA FILMS MADE THEREFROM

(71) Applicant: VERSUM MATERIALS US, LLC, TEMPE, AZ (US)

(72) Inventors: MATTHEW R. MACDONALD, MISSION VIEJO, CA (US); XINJIAN LEI, VISTA, CA (US); MICHAEL JAMES FOODY, PHOENIX, AZ (US)

(21) Appl. No.: 18/701,169

(22) PCT Filed: Oct. 11, 2022
(86) PCT No.: PCT/US2022/077912

§ 371 Date: Apr. 12, 2024

Related U.S. Application Data
(60) Provisional application No. 63/255,323, filed on Oct. 13, 2021.

(51) Int. Cl. B05D 1/00; C07F 7/18; C23C 16/505; C23C 16/52

(52) U.S. Cl. CPC B05D 1/62; C07F 7/1804; C23C 16/505; C23C 16/52

(57) ABSTRACT

A method for making a dense organosilicon film with improved mechanical properties includes the steps of: providing a substrate within a reaction chamber; introducing into the reaction chamber a gaseous composition comprising alkoxy silane; and applying energy to the gaseous composition comprising alkoxysilane in the reaction chamber to induce reaction of the gaseous composition comprising alkoxysilane to deposit an organosilicon film on the substrate, wherein the organosilicon film has a dielectric constant of from ˜2.40 to ˜3.20, an elastic modulus of from ˜6 to ˜30 GPa, and an at. % carbon of from ˜10 to ˜45 as measured by XPS.

### CROSS-REFERENCE TO RELATED APPLICATIONS

This application claims the benefit of U.S. Provisional Application No. 63/255,323, filed Oct. 13, 2021, which is hereby incorporated in its entirety.

### BACKGROUND OF THE INVENTION

Described herein is a composition and method for formation of a dense organosilica dielectric film using an alkoxysilane as a precursor to the film. More specifically, described herein is a composition and chemical vapor deposition (CVD) method for forming a dense film having a dielectric constant k ranging from ˜2.4 to ˜3.2 wherein the film has a high elastic modulus and excellent resistance to plasma induced damage as compared to films made from conventional precursors.

The electronics industry utilizes dielectric materials as insulating layers between circuits and components of integrated circuits (IC) and associated electronic devices. Line dimensions are being reduced in order to increase the speed and memory storage capability of microelectronic devices (e.g., computer chips). As the line dimensions decrease, the insulating requirements for the interlayer dielectric (ILD) become much more rigorous. Shrinking the spacing requires a lower dielectric constant to minimize the RC time constant, where R is the resistance of the conductive line and C is the capacitance of the insulating dielectric interlayer. Capacitance (C) is inversely proportional to spacing and proportional to the dielectric constant (k) of the interlayer dielectric (ILD). Conventional silica (SiO₂) CVD dielectric films produced from SiH₄ or TEOS (Si(OCH₂CH₃)₄, tetraethylorthosilicate) and O₂ have a dielectric constant k greater than 4.0. There are several ways in which industry has attempted to produce silica-based CVD films with lower dielectric constants, the most successful being the doping of the insulating silicon oxide film with organic groups providing dielectric constants ranging from about 2.4 to about 3.5. This organosilica glass (OSG) is typically deposited as a dense film (density ˜1.5 g/cm³) from an organosilicon precursor, such as a methylsilane or siloxane, and an oxidant, such as O₂ or N₂O.

Patents, published applications, and publications in the field of porous ILD by CVD methods field include EP 1 119 035 A2 and U.S. Pat. No. 6,171,945, which describe a process of depositing an OSG film from organosilicon precursors with labile groups in the presence of an oxidant such as N₂O and optionally a peroxide, with subsequent removal of the labile group with a thermal anneal to provide porous OSG; U.S. Pat. Nos. 6,054,206 and 6,238,751, which teach the removal of essentially all organic groups from deposited OSG with an oxidizing anneal to obtain porous inorganic SiO₂; EP 1 037 275, which describes the deposition of an hydrogenated silicon carbide film which is transformed into porous inorganic SiO₂ by a subsequent treatment with an oxidizing plasma; and U.S. Pat. No. 6,312,793 B1, WO 00/24050, and a literature article Grill, A. Patel, V. Appl. Phys. Lett. (2001), 79 (6), pp. 803-805, which all teach the co-deposition of a film from an organosilicon precursor and an organic compound, and subsequent thermal anneal to provide a multiphase OSG/organic film in which a portion of the polymerized organic component is retained. In the latter references, the ultimate final composition of the films indicate residual porogen and a high hydrocarbon film content of approximately 80 to 90 atomic %. Further, the final films retain the SiO₂-like network, with substitution of a portion of oxygen atoms for organic groups.

US Patent appl No. U.S. Pat. No. 201,110,113,184A discloses a class of materials that can be used to deposit insulating films with dielectric constants ranging from ˜k=2.4 to k=2.8 via a PECVD process. The materials comprise Si compounds that have 2 hydrocarbon groups that can be bound to each other to form a cyclic structure in cooperation with a Si atom or having ≥1 branched hydrocarbon group. In the branched hydrocarbon group, an α-C which is a C atom bound to a Si atom constitutes a methylene group, and a β-C which is a C atom bound to the methylene group or a γ-C which is a C atom bound to the β-C is the branching point. Specifically two of the alkyl groups bonded to the Si include CH₂CH(CH₃)CH₃, CH₂CH(CH₃)CH₂CH₃, CH₂CH₂CH(CH₃)CH₃, CH₂C(CH₃)₂CH₃ and CH₂CH₂CH(CH₃)₂CH₃, and a third group bonded to the silicon includes OCH₃ and OC₂H₅. Although this invention claims that a high density of SiCH₂Si groups forms within the as deposited film via plasma dissociation of the alkyl group R from SiCH₂R, the examples in the patent application clearly indicate that a high density of SiCH₂Si groups only occurs after the films are exposed to ultraviolet irradiation. The formation of SiCH₂Si groups upon exposure to ultraviolet irradiation has been well documented in the literature. In addition the k values reported for these films are low, less than or equal to 2.8.

US Patent appl No. U.S. Pat. No. 2,020,075,321 A discloses a method of forming a low-k carbon-doped silicon oxide (CDO) layer having a high hardness by a plasma-enhanced chemical vapor deposition (PECVD) process. The method includes providing a carrier gas at a carrier gas flow rate and a CDO precursor at a precursor flow rate to a process chamber. A radio frequency (RF) power is applied at a power level and a frequency to the CDO precursor. The CDO layer is deposited on a substrate within the process chamber.

WO21050798 A1 [EN] A method for making a dense organosilicon film with improved mechanical properties, the method comprising the steps of: providing a substrate within a reaction chamber; introducing into the reaction chamber a gaseous composition comprising a novel mono- or dialkoxysilane; and applying energy to the gaseous composition comprising the novel mono- or dialkoxysilane in the reaction chamber to induce reaction of the gaseous composition comprising the novel mono- or dialkoxysilane to deposit an organosilicon film on the substrate, wherein the organosilicon film has a dielectric constant of from about 2.8 to about 3.3, an elastic modulus of from about 7 to about 30 GPa, and an at. percent carbon of from about 10 to about 30 as measured by XPS.

WO21050659 A1 discloses a method for making a dense organosilicon film with improved mechanical properties, the method comprising the steps of: providing a substrate within a reaction chamber; introducing into the reaction chamber a gaseous composition comprising a novel monoalkoxysilane; and applying energy to the gaseous composition comprising a novel monoalkoxysilane in the reaction chamber to induce reaction of the gaseous composition comprising a novel monoalkoxysilane to deposit an organosilicon film on the substrate, wherein the organosilicon film has a dielectric constant of from about 2.80 to about 3.30, an elastic modulus of from about 9 to about 32 GPa, and an at. percent carbon of from about 10 to about 30 as measured by XPS.

Plasma or process induced damage (PID) in low k films is caused by the removal of carbon from the film during plasma exposure, particularly during etch and photoresist strip processes. This changes the plasma damaged region from hydrophobic to hydrophilic. Exposure of the hydrophilic SiO₂ like damaged layer to dilute HF-based wet chemical post plasma treatments (with or without additives such as surfactants) results in rapid dissolution of this layer. In patterned low k wafers, this results in profile erosion. Process induced damage and the resulting profile erosion in low k films is a significant problem that device manufacturers must overcome when integrating low k materials in a ULSI interconnect.

Films with increased mechanical properties (higher elastic modulus, higher hardness) reduce line edge roughness in patterned features, reduce pattern collapse, and provide greater internal mechanical stress within an interconnect, reducing failures due to electromigration. Thus, there is a need for low k films with excellent resistance to PID and the highest possible mechanical properties at a given dielectric constant. The precursors in this invention are targeting the most advanced technology nodes, typically films with dielectric constants between ˜2.4 and 3.2.

### BRIEF SUMMARY OF THE INVENTION

The methods and compositions described herein fulfill one or more needs described above. The alkoxysilane precursor can be used to deposit dense low k films with k values between about 2.40 to about 3.20, such films exhibiting an unexpectedly high elastic modulus/hardness, and an unexpectedly high resistance to plasma induced damage.

In one aspect, a method is provided for making a dense organosilica film with improved mechanical properties, the method comprising the steps of: providing a substrate within a reaction chamber; introducing into the reaction chamber a gaseous composition comprising at least one alkoxysilane compound having the structure of Formula I:

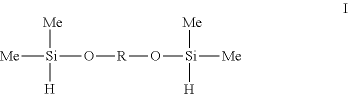

wherein R is an organic moiety derived from the group consisting of a linear or branched C₂ to C₅ alkane, a linear or branched C₂ to C₅ alkene, a linear or branched C₂ to C₅ alkyne, a C₄ to C₁₀ cyclic alkane, a C₄ to C₁₀ cyclic alkene, a C₅ to C₁₀ arene. For the above Formula I, combinations of alkyl groups are preferably selected such that the alkoxysilane compound's boiling point is less than 250° C. In addition for optimum performance the alkyl groups preferably are chosen so that the carbon atoms bonded to the oxygen atoms are secondary or tertiary carbon, thus resulting in more stable secondary or tertiary carbon radicals upon homolytic bond dissociation (e.g., SiO—R—OSi→SiO·+SiO—R—, wherein SiO—R— is a primary, or secondary or tertiary radical). Energy is then applied to the gaseous composition comprising the alkoxysilane in the reaction chamber to induce reaction of the gaseous composition comprising the alkoxysilane to deposit an organosilica film on the substrate. According to an exemplary embodiment the organosilica film has a dielectric constant of from ˜2.40 to ˜3.20 and an elastic modulus of from ˜6 to ˜30 GPa, preferably from ˜6 to ˜25 GPa. According to another embodiment the film further includes at. % carbon of from ˜10 to ˜45 as measured by XPS.

### BRIEF DESCRIPTION OF THE DRAWINGS

FIG. 1 is a FTIR spectrum for a film deposited using 1,4-bis(dimethylsiloxy)cyclohexane under conditions described in Example 3.

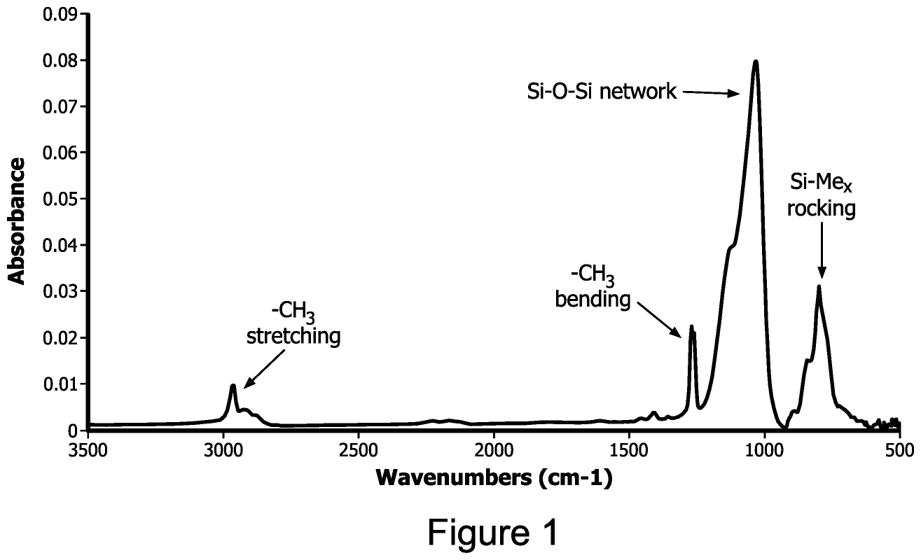

### DETAILED DESCRIPTION OF THE INVENTION

Described herein is a chemical vapor deposition method for making a dense organosilica film with improved mechanical properties, the method comprising the steps of: providing a substrate within a reaction chamber; introducing into the reaction chamber a gaseous composition comprising an alkoxysilane, a gaseous oxidant such as O₂ or N₂O, and an inert gas such as He; and applying energy to the gaseous composition comprising the alkoxysilane in the reaction chamber to induce reaction of the gaseous composition comprising the alkoxysilane to deposit an organosilica film on the substrate. According to an exemplary embodiment the organosilica film has a dielectric constant of from ˜2.40 to ˜ 3.20, an elastic modulus of from ˜6 to ˜30 GPa, and an at. % carbon of from ˜10 to ˜45 as measured by XPS, preferably a dielectric constant of from ˜2.80 to ˜3.00, an elastic modulus of from ˜7 to ˜23 GPa, and an at. % carbon from ˜12 to ˜43 as measured by XPS.

Also described herein is a method for making a dense organosilica film with improved mechanical properties, the method comprising the steps of: providing a substrate within a reaction chamber; introducing into the reaction chamber a gaseous composition comprising an alkoxysilane a gaseous oxidant such as O₂ or N₂O, and an inert gas such as He; and applying energy to the gaseous composition comprising the alkoxysilane to deposit an organosilica film on the substrate. According to an exemplary embodiment the organosilica film has a dielectric constant of from ˜2.40 to ˜3.20 and an elastic modulus of from ˜6 to ˜30 GPa.

The alkoxysilane provides unique attributes that make it possible to achieve a relatively low dielectric constant for a dense organosilica film and to surprisingly exhibit excellent mechanical properties compared to prior art structure former precursors such as diethoxymethylsilane (DEMS) and 1-ethoxy-1-methylsilacyclopentane (MESCP). Not bound by theory, it is believed alkoxysilanes in this invention can provide stable secondary or tertiary diradicals which help facilitate the formation of disilylmethylene groups (i.e. Si—CH₂—Si moieties) in the as-deposited film.

It is well known by those practicing in the field of organic chemistry that more energy must be supplied to generate a primary hydrocarbon radical (such as an ethyl radical, CH₃CH₂·) than a secondary hydrocarbon radical (such as an isopropyl radical (CH₃)₂CH·). This is due to the greater stability of the isopropyl radical relative to the ethyl radical. The same principle applies to the homolytic bond dissociation of the oxygen-carbon bond in silicon alkoxy groups; it requires less energy to dissociate the oxygen-carbon bond in an iso-propoxysilane than in an ethoxysilane. Similarly, it takes less energy to dissociate the silicon-carbon bond in an iso-propylsilane than in an ethylsilane. It is assumed that bonds that require less energy to break are more readily dissociated in a plasma. Thus, alkoxysilanes having Si—OPrⁱ, or Si—OBu^{s} or Si—OBu^{t} groups could result in a higher density of SiO· type radicals relative to those having Si-OEt group in a plasma. Likewise alkoxysilanes having Si-Et, or Si—Prⁱ, Si-Bu^{s} or Si-Bu^{t} groups could result in a higher density of Si-type radicals relative to those having just Si-Me groups in a plasma. Presumably this contributes to the differentiated properties of deposited using alkoxysilanes having Si-OEt, Si—OPrⁱ, or Si-OBu^{s} or Si-OBu^{t} moieties built into the R group of Formula I relative to alkoxysilanes having Si—OMe. Importantly the SiO—R—OSi linkage could provide SiO—R· radicals which is more stable than hydrocarbon radicals due to the oxygen-carbon bond, thus allowing potentially generation of more disilylmethyene linkages in the as-deposited silicon-containing films.

Without intending to be bound by theory, it is believed that there may be advantages of the alkoxysilane compounds having Formula I over simple alkoxysilanes like TEOS (tetraethoxysilane), MTES (methyltriethoxysilane), DEMS (diethoxymethylsilane), or dimethylmethoxysilane with respect to their use as precursors for depositing a dense organosilica film. Specifically, the alkoxysilane compounds having Formula I described herein have two silicon atoms instead of one, which may lead to higher deposition rates and/or more efficient deposition of silicon atoms onto the substrate surface. In addition, the alkoxy moieties in these molecules are derived from diols, which bridge the two silicon atoms together such that they are in close proximity to each other when the precursor reacts with the plasma reactant gas and with the substrate surface. Also, the radicals that are believed to be generated on the carbon atom(s) of the R group in Formula I may have better stability and/or better ability to form a densely networked organosilica film on the substrate compared to those radical species generated from terminal alkoxy groups such as methoxy, ethoxy, iso-propoxy, sec-butoxy, and tert-butoxy.

Some of advantages over prior achieved with alkoxysilanes as silicon precursors include but are not limited to:
✓ Lower cost and easy to synthesize
✓ High elastic modulus
✓ High wide range of XPS carbon
✓ High disilylmethyene density
✓ High variable % of Si(CH₃)₂ or Si(CH₃)CH₂Si in the Si(CH₃)ₓ IR band
✓ High deposition rate

In one aspect, a method is provided for making a dense organosilica film with improved mechanical properties, the method comprising the steps of: providing a substrate within a reaction chamber; introducing into the reaction chamber a gaseous composition comprising at least one alkoxysilane compound having the structure of Formula I:

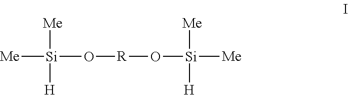

wherein R is an organic moiety derived from the group consisting of a linear or branched C₂ to C₅ alkane, a linear or branched C₂ to C₅ alkene, a linear or branched C₂ to C₅ alkyne, a C₄ to C₁₀ cyclic alkane, a C₄ to C₁₀ cyclic alkene, a C₅ to C₁₀ arene; with or without an oxygen source. For the above Formula I combinations of alkyl groups are selected such that the molecule's boiling point is less than 200° C. In addition for optimum performance the R groups are chosen that potentially form secondary or tertiary radicals upon homolytic bond dissociation (e.g., SiO—R—OSi→SiO·+SiO—R·, wherein SiO—R· is a primary, or secondary or tertiary radical. The resulting SiO—R· radicals are expected to react with Si-Me groups to create Si—CH₂—Si linkages which help increase disilylmethyene density. Energy is then applied to the gaseous composition comprising the alkoxysilane in the reaction chamber to induce reaction of the gaseous composition comprising the alkoxysilane to deposit an organosilicon film on the substrate. According to an exemplary embodiment the organosilica film has a dielectric constant of from ˜2.40 to ˜3.20 and an elastic modulus of from ˜6 to ˜ 25 GPa. The substrate temperature may also have an impact on the properties of the resulting dense orgaosilica films, for example higher temperatures such as 300 to 400° C., or 350 to 400° C., may be preferred. In certain embodiments, the oxygen source is selected from the group consisting of water vapor, water plasma, ozone, oxygen, oxygen plasma, oxygen/helium plasma, oxygen/argon plasma, nitrogen oxides plasma, carbon dioxide plasma, hydrogen peroxide, organic peroxides, and mixtures thereof.

In yet another aspect, there is provided a composition comprising at least one alkoxysilane compound having the structure of Formula I:

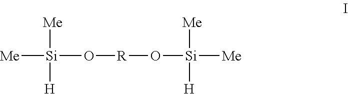

wherein R is an organic moiety derived from the group consisting of a linear or branched C₂ to C₅ alkane, a linear or branched C₂ to C₅ alkene, a linear or branched C₂ to C₅ alkyne, a C₄ to C₁₀ cyclic alkane, a C₄ to C₁₀ cyclic alkene, a C₅ to C₁₀ arene. Table 1 lists preferred alkoxysilanes having Formula I.

TABLE 1
List of preferred alkoxysilanes having Formula I.

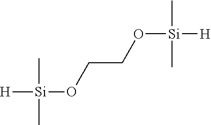

1,2-bis(dimethylsiloxy)ethane

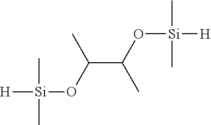

2,3-bis(dimethylsiloxy)butane

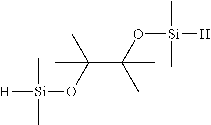

2,3-bis(dimethylsiloxy)-2,3-
dimethylbutane

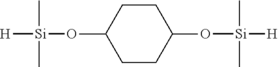

1,4-bis(dimethylsiloxy)cyclohexane

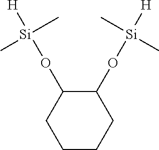

1,2-bis(dimethylsiloxy)cyclohexane

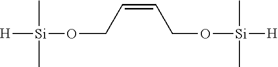

1,4-bis(dimethylsiloxy)-cis-2-butene

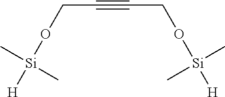

1,4-bis(dimethylsiloxy)-2-butyne

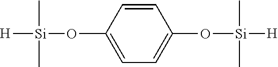

1,4-bis(dimethylsiloxy)benzene

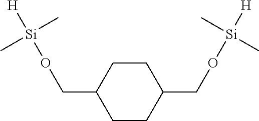

1,4-
bis(dimethylsiloxymethyl)cyclohexane

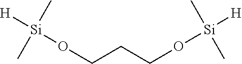

1,3-bis(dimethylsiloxy)propane

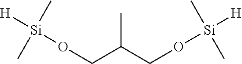

1,3-bis(dimethylsiloxy)-2-methylpropane

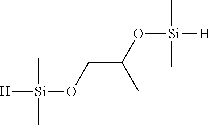

1,2-bis(dimethylsiloxy)propane

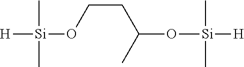

1,3-bis(dimethylsiloxy)butane

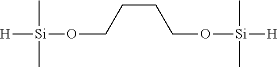

1,4-bis(dimethylsilyl)butane

The alkoxysilanes described herein may be synthesized by several routes. One route involves reacting the corresponding diol (which comprises two-OH groups) with tetramethyldisilazane, as shown in Equation 1.

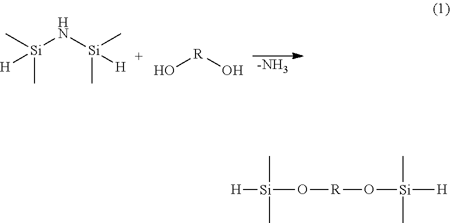

Another route involves the reaction of the corresponding diol with an aminodimethylsilane like dimethylaminodimethylsilane, as shown in Equation 2.

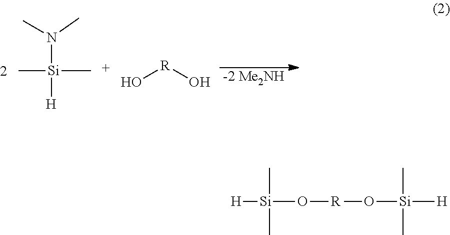

Another route involves the reaction of the corresponding diol with tetramethyldisiloxane, as shown in Equation 3.

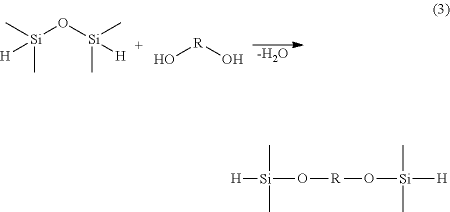

Another route involves the reaction of the corresponding diol with an alkoxydimethylsilane like dimethylethoxysilane as shown in Equation 4.

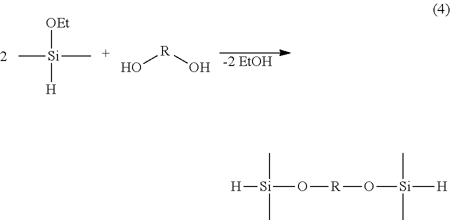

Another route involves the reaction of the corresponding diol with chlorodimethylsilane as shown in Equation 5.

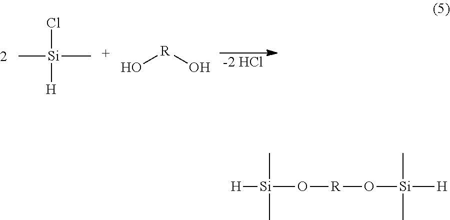

Alternatively, the reaction shown in Equation 5 could be performed in the presence of an amine base or some other type of HCl scavenger to drive the reaction to completion.

Another route involves a two-step process, the first step comprising the metalation of the corresponding diol with an organolithium reagent (e.g. n-butyllithium), a different organometal reagent (e.g. dibutylmagenesium), a metal amide (e.g. LiNⁱPr₂ or NaN(SiMe₃)₂), a Grignard reagent (e.g. MeMgCl), or a metal hydride reagent (e.g. LiH, NaH, KH, CaH₂), to generate first the metallated diolate intermediate. The second step comprises reacting that metallated diolate with either an alkoxydimethylsilane, tetramethyldisiloxane, or chlorodimethylsilane. An example of this two-step process is shown in Equation 6.

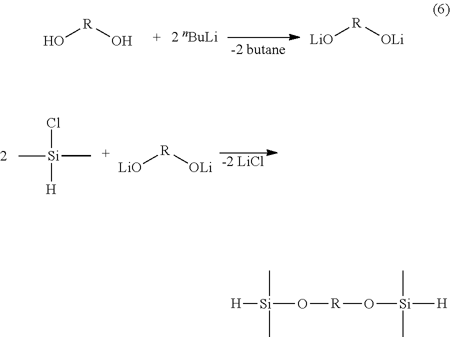

In the formula above and throughout the description, the term “alkane” denotes a linear or branched functional group having from 1 to 10 carbon atoms which is bonded to two oxygen atoms. Exemplary linear alkyl groups include, but are not limited to, ethane, propane, n-butane. Exemplary branched alkyl groups include, but are not limited to, iso-butane, 2,3-dimethylbutane.

In the formula above and throughout the description, the term “cyclic alkane” denotes a cyclic functional group having from 3 to 10 carbon atoms which is bonded to two oxygen atoms. Exemplary cyclic alkyl groups include, but are not limited to, cyclopentane, cyclohexane.

In the formulae above and throughout the description, the term “alkene” denotes a group which has one or more carbon-carbon double bonds and has from 2 to 10 or from 2 to 6 carbon atoms which is bonded to two oxygen atoms.

In the formulae above and throughout the description, the term “alkyne” denotes a group which has one or more carbon-carbon triple bonds and has from 2 to 10 or from 2 to 6 carbon atoms which is bonded to two oxygen atoms.

In the formulae above and throughout the description, the term “arene” denotes an aromatic cyclic functional group having from 3 to 10 carbon atoms, from 5 to 10 carbon atoms, or from 6 to 10 carbon atoms which is bonded to two oxygen atoms. Exemplary aryl groups include, but are not limited to benzene and toluene.

In the formulae above and throughout the description, the term “secondary carbon” denotes a carbon bonded to two carbon atoms.

In the formulae above and throughout the description, the term “tertiary carbon” denotes a carbon bonded to three carbon atoms.

Throughout the description, the symbol “˜” refers about 5.0% deviation from the value, for example ˜3.00 denotes about 3.00 (+0.15).

The alkoxysilanes having Formula I according to the present invention and compositions comprising the alkoxysilanes compounds having Formula I according to the present invention are preferably substantially free of halide ions. As used herein, the term “substantially free” as it relates to halide ions (or halides) such as, for example, chlorides (i.e. chloride-containing species such as HCl or silicon compounds having at least one Si—Cl bond) and fluorides, bromides, and iodides, means less than 5 ppm (by weight) measured by ion chromatography (IC), preferably less than 3 ppm measured by IC, and more preferably less than 1 ppm measured by IC, and most preferably 0 ppm measured by IC. Chlorides are known to act as decomposition catalysts for the silicon precursor compounds having Formula I. Significant levels of chloride in the final product can cause the silicon precursor compounds to degrade. The gradual degradation of the silicon precursor compounds may directly impact the film deposition process making it difficult for the semiconductor manufacturer to meet film specifications. In addition, the shelf-life or stability is negatively impacted by the higher degradation rate of the silicon precursor compounds thereby making it difficult to guarantee a 1-2 year shelf-life. Therefore, the accelerated decomposition of the silicon precursor compounds presents safety and performance concerns related to the formation of these flammable and/or pyrophoric gaseous byproducts. The alkoxysilanes having Formula I are preferably substantially free of metal ions such as, Li⁺, Na⁺, K⁺, Mg²⁺, Ca²⁺, Al³⁺, Fe²⁺, Fe³⁺, Ni²⁺, Cr³⁺. As used herein, the term “substantially free” as it relates to Li, Na, K, Mg, Ca, Al, Fe, Ni, Cr means less than 5 ppm (by weight), preferably less than 3 ppm, and more preferably less than 1 ppm, and most preferably 0.1 ppm as measured by ICP-MS. In some embodiments, the silicon precursor compounds having Formula I are free of metal ions such as, Li⁺, Na⁺, K⁺, Mg²⁺, Ca²⁺, Al³⁺, Fe²⁺, Fe³⁺, Ni²⁺, Cr³⁺. As used herein, the term “free of” metal impurities as it relates to Li, Na, K, Mg, Ca, Al, Fe, Ni, Cr, means less than 1 ppm, preferably 0.1 ppm (by weight) as measured by ICP-MS, most preferably 0.05 ppm (by weight) as measured by ICP-MS or other analytical method for measuring metals.

In addition, the alkoxysilanes having Formula I preferably have a purity of 98 wt. % or higher, more preferably 99 wt. % or higher as measured by GC when used as a precursor to deposit dense orgaosilica films. Importantly the alkoxysilanes compounds having Formula I are preferably substantially free of oxygen-containing or nitrogen-containing impurities which are from either starting materials employed during synthesis or by-products generated during synthesis. Examples include but not limited to, water, tetramethyldisiloxane, organic amines such as triethylamine, pyridine and any other organic amines used to promote the reaction. As used herein, the term “free of” oxygen-containing or nitrogen-containing impurities as it relates to tetramethyldisiloxane, tetramethyldisilazane, water, organic amines such as triethylamine, pyridine and any other organic amines, means 1000 ppm or less, preferably 500 ppm or less (by weight) as measured by GC, most preferably 100 ppm or less (by weight) as measured by GC or other analytical method for assay. The oxygen-containing impurities as defined herein are compounds having at least one oxygen atom and are either from staring materials or generated from the synthesis of alkoxysilanes compounds having Formula I. Those oxygen-containing impurities may have close boiling point to the alkoxysilanes compounds having Formula I, thus remaining in the product after purification. Likewise, the nitrogen-containing impurities as defined herein are compounds having at least one nitrogen atom and are either from staring materials or generated from the synthesis of alkoxysilanes compounds having Formula I. Those nitrogen-containing impurities may have close boiling point to the alkoxysilanes compounds having Formula I, thus remaining in the product after purification.

The low k dielectric films such as organosilicates are organosilica glass (“OSG”) films or materials. Organosilicates are employed in the electronics industry, for example, as low k materials. Material properties depend upon the chemical composition and structure of the film. Since the type of organosilicon precursor has a strong effect upon the film structure and composition, it is beneficial to use precursors that provide the required film properties to ensure that the addition of the needed amount of porosity to reach the desired dielectric constant does not produce films that are mechanically unsound. The method and composition described herein provides the means to generate low k dielectric films that have a desirable balance of electrical and mechanical properties as well as other beneficial film properties as high carbon content to provide improved integration plasma resistance.

In certain embodiments of the method and composition described herein, a layer of silicon-containing dielectric material is deposited on at a least a portion of a substrate via a chemical vapor deposition (CVD) process employing a reaction chamber. The method thus includes the step of providing a substrate within a reaction chamber. Suitable substrates include, but are not limited to, semiconductor materials such as gallium arsenide (“GaAs”), silicon, and compositions containing silicon such as crystalline silicon, polysilicon, amorphous silicon, epitaxial silicon, silicon dioxide (“SiO₂”), silicon glass, silicon nitride, fused silica, glass, quartz, borosilicate glass, and combinations thereof. Other suitable materials include chromium, molybdenum, and other metals commonly employed in semi-conductor, integrated circuits, flat panel display, and flexible display applications. The substrate may have additional layers such as, for example, silicon, SiO₂, organosilicate glass (OSG), fluorinated silicate glass (FSG), boron carbonitride, silicon carbide, hydrogenated silicon carbide, silicon nitride, hydrogenated silicon nitride, silicon carbonitride, hydrogenated silicon carbonitride, boronitride, organic-inorganic composite materials, photoresists, organic polymers, porous organic and inorganic materials and composites, metal oxides such as aluminum oxide, and germanium oxide. Still further layers can also be germanosilicates, aluminosilicates, copper and aluminum, and diffusion barrier materials such as, but not limited to, TIN, Ti(C) N, TaN, Ta(C) N, Ta, W, or WN.

The reaction chamber is typically, for example, a thermal CVD or a plasma enhanced CVD reactor or a batch furnace type reactor in a variety of ways. In one embodiment, a liquid delivery system may be utilized. In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

The method disclosed herein includes the step of introducing into the reaction chamber a gaseous composition comprising an alkoxysilane. In some embodiments, the composition may include additional reactants such as, for example, oxygen-containing species such as, for example, O₂, O₃, and N₂O, gaseous or liquid organic substances, CO₂, or CO. In one particular embodiment, the reaction mixture introduced into the reaction chamber comprises the at least one oxidant selected from the group consisting of O₂, N₂O, NO, NO₂, CO₂, water, H₂O₂, ozone, and combinations thereof. In an alternative embodiment, the reaction mixture does not comprise an oxidant.

The composition for depositing the dielectric film described herein comprises: from about 40 to about 100 weight percent of alkoxysilane in a solvent which can be delivered into the reaction chamber via direct liquid inject (DLI).

In embodiments, the gaseous composition comprising the alkoxysilane can be used with hardening additives to further increase the elastic modulus of the as deposited films.

In embodiments, the gaseous composition comprising the alkoxysilane is substantially free of or free of halides such as, for example, chlorides.

In addition to the alkoxysilane, additional materials can be introduced into the reaction chamber prior to, during and/or after the deposition reaction. Such materials include, e.g., inert gas (e.g., He, Ar, N₂, Kr, Xe, etc., which may be employed as a carrier gas for lesser volatile precursors and/or which can promote the curing of the as-deposited materials and provide a more stable final film).

Any reagent employed, including the alkoxysilane can be carried into the reactor separately from distinct sources or as a mixture. The reagents can be delivered to the reactor system by any number of means, preferably using a pressurizable stainless steel vessel fitted with the proper valves and fittings to allow the delivery of liquid to the process reactor. Preferably, the precursor is delivered into the process vacuum chamber as a gas, that is, the liquid must be vaporized before it is delivered into the process chamber.

In other embodiments, the method disclosed herein includes the step of introducing into the reaction chamber a gaseous composition comprising a mixture of a 1-alkoxy-1-methylsilacyclopentane and alkoxysilane.

The method disclosed herein includes the step of applying energy to the gaseous composition comprising the alkoxysilane in the reaction chamber to induce reaction of the gaseous composition comprising the alkoxysilane to deposit an organosilica film on the substrate, wherein the organosilica film has a dielectric constant of from ˜2.40 to ˜3.20 in some embodiments, ˜2.40 to ˜3.00 in other embodiments, ˜2.40 to ˜2.90, and ˜2.80 to ˜ 3.00 in still preferred embodiments; an elastic modulus of from ˜2 to ˜30 GPa, preferably from 3 to 23 GPa; and an at. % carbon of from ˜10 to ˜45 as measured by XPS. Energy is applied to the gaseous reagents to induce the alkoxysilane and other reactants, if present, to react and to form the film on the substrate. Such energy can be provided by, e.g., plasma, pulsed plasma, helicon plasma, high density plasma, inductively coupled plasma, remote plasma, hot filament, and thermal (i.e., non-filament) and methods. A secondary rf frequency source can be used to modify the plasma characteristics at the substrate surface. Preferably, the film is formed by plasma-enhanced chemical vapor deposition (“PECVD”).

The flow rate for each of the gaseous reagents preferably ranges from 10 to 5000 sccm, more preferably from 30 to 3000 sccm, per single 300 mm wafer. The actual flow rates needed may depend upon wafer size and chamber configuration, and are in no way limited to 300 mm wafers or single wafer chambers.

In certain embodiments, the film is deposited at a deposition rate of from about ˜5 to ˜200 nanometers (nm) per minute. In other embodiments, the film is deposited at a deposition rate of from about 30 to 200 nanometers (nm) per minute.

The pressure in the reaction chamber during deposition typically ranges from about 0.01 to about 600 torr or from about 1 to 15 torr.

The film is preferably deposited to a thickness of 0.001 to 500 microns, although the thickness can be varied as required. The blanket film deposited on a non-patterned surface has excellent uniformity, with a variation in thickness of less than 3% over 1 standard deviation across the substrate with a reasonable edge exclusion, wherein e.g., a 5 mm outermost edge of the substrate is not included in the statistical calculation of uniformity.

In addition to the inventive OSG products, the present invention includes the process by which the products are made, methods of using the products and compounds and compositions useful for preparing the products. For example, a process for making an integrated circuit on a semiconductor device is disclosed in U.S. Pat. No. 6,583,049, which is herein incorporated by reference.

The dense organosilica films produced by the disclosed methods exhibit excellent resistance to plasma induced damage, particularly during etch and photoresist strip processes.

The dense organosilica films produced by the disclosed methods exhibit excellent mechanical properties for a given dielectric constant relative to dense organosilica films having the same dielectric constant but made from a precursor that is not an alkoxysilane. The resulting organosilica film (as deposited) typically has a dielectric constant of from ˜ 2.40 to ˜3.20 in some embodiments, ˜2.80 to ˜3.10 in other embodiments, and ˜2.40 to ˜ 3.00 in still other embodiments, an elastic modulus of from ˜6 to ˜30 GPa, and an at. % carbon of from ˜10 to ˜45 as measured by XPS. In some embodiments, as it is believed that incorporation of nitrogen could potentially increase the dielectric of the dense organosilica films, thus it is expected that the nitrogen content is 0.1 at. % or less, preferably 0.1 at. % or less, most preferably 0.01 at. % or less as measured by XPS, SIMS or RBS or any analytical methods. In addition, the organosilica film has a relative disilylmethylene density from ˜1 to ˜30, or ˜5 to ˜30, or ˜10 to ˜30 or ˜1 to ˜20 as calculated from the FTIR spectra. In some embodiments, the organosilica film is deposited at a rate of from ˜5 nm/min to ˜1000 nm/min, or ˜50 nm/min to ˜1000 nm/min. In other embodiments, the organosilica film is deposited with a higher rate of from ˜100 nm/min to ˜2000 nm/min, or ˜ 200 nm/min to ˜2000 nm/min, or ˜500 nm/min to ˜2000 nm/min. Importantly it is expected the alkoxysilanes having Formula I would provide a higher deposition rate than other alkoxysilanes as they have the pre-existing Si—R—Si linkage.

The resultant dense organosilica films may also be subjected to a post treating process once deposited. Thus, the term “post-treating” as used herein denotes treating the film with energy (e.g., thermal, plasma, photon, electron, microwave, etc.) or chemicals to further enhance materials properties.

The conditions under which post-treating are conducted can vary greatly. For example, post-treating can be conducted under high pressure or under a vacuum ambient.

UV annealing is a preferred method conducted under the following conditions.

The environment can be inert (e.g., nitrogen, CO₂, noble gases (He, Ar, Ne, Kr, Xe), etc.), oxidizing (e.g., oxygen, air, dilute oxygen environments, enriched oxygen environments, ozone, nitrous oxide, etc.) or reducing (dilute or concentrated hydrogen, hydrocarbons (saturated, unsaturated, linear or branched, aromatics), etc.). The pressure is preferably about 1 Torr to about 1000 Torr. However, a vacuum ambient is preferred for thermal annealing as well as any other post-treating means. The temperature is preferably 200-500° C., and the temperature ramp rate is from 0.1 to 100 deg° C./min. The total UV annealing time is preferably from 0.01 min to 12 hours.

The invention will be illustrated in more detail with reference to the following Examples, but it should be understood that it is not deemed to be limited thereto. It is also recognized that the precursors described in this invention can also be used to deposit porous low k films with similar process advantages relative to existing porous low k films (that is a higher elastic modulus and greater resistance to plasma induced damage for a given value of the dielectric constant).

### Examples

Some experiments were performed on a 300 mm AMAT Producer SE, which deposits films on two wafers at the same time. Thus, the precursor and gas flow rates correspond to the flow rates required to deposit films on two wafers at the same time. The stated RF power per wafer is correct, as each wafer processing station has its own independent RF power supply. The stated deposition pressure is correct, as both wafer processing stations are maintained at the same pressure. Other experiments were performed on a 200 mm AMAT P5000 platform to provide various dense organosilica films on a single wafer. The deposition chamber is equipped with a RF power supply amenable to industry standard PECVD processing.

Although illustrated and described above with reference to certain specific embodiments and examples, the present invention is nevertheless not intended to be limited to the details shown. Rather, various modifications may be made in the details within the scope and range of equivalents of the claims and without departing from the spirit of the invention. It is expressly intended, for example, that all ranges broadly recited in this document include within their scope all narrower ranges which fall within the broader ranges. It is also recognized that the hydrido-dimethyl-alkoxysilanes disclosed in this invention can be used as a structure former for the deposition of porous low k films with a high elastic modulus, a high XPS carbon content, and a high resistance to plasma induced damage.

Thickness and refractive index were measured on a Woollam model M2000 Spectroscopic Ellipsometer. Dielectric constants were determined using Hg probe technique on mid-resistivity p-type wafers (range 8-12 ohm-cm). FTIR spectra were measured using a Thermo Fisher Scientific Model iS50 spectrometer fitted with a nitrogen purged Pike Technologies Map300 for handling 12-inch wafers. FTIR spectra were used to calculate the relative density of bridging disilylmethylene groups in the film. The density of bridging disilylmethylene groups in the film (i.e., the SiCH₂Si density), as determined by infrared spectroscopy, is defined as 1E4 times the area of the SiCH₂Si infrared band centered near 1360 cm 1 divided by the area of the SiOₓ bands between approximately 1250 cm⁻¹ to 920 cm⁻¹. Peaks corresponding to the CH₃ stretching, anti-symmetric bending, and symmetric bending are centered at ˜2960 cm 1, 1410 cm 1, and 1274 cm⁻¹ respectively. Bond stretching vibrational modes for Hₓ—SiO are observed as a broad peak ranging from 2100 cm⁻¹ to 2300 c⁻¹. Mechanical properties were determined using a KLA iNano Nano Indenter.

Compositional data were obtained by X-ray photoelectron spectroscopy (XPS) on either a PHI 5600 (73560, 73808) or a Thermo K-Alpha (73846) and are provided in atomic weight percent. The atomic weight percent (%) values reported in the table do not include hydrogen.

Although illustrated and described above with reference to certain specific embodiments and examples, the present invention is nevertheless not intended to be limited to the details shown. Rather, various modifications may be made in the details within the scope and range of equivalents of the claims and without departing from the spirit of the invention. It is expressly intended, for example, that all ranges broadly recited in this document include within their scope all narrower ranges which fall within the broader ranges. It is also recognized that the alkoxysilanes disclosed in this invention can be used as a structure former for the deposition of porous low k films with a high elastic modulus, a high XPS carbon content, and a high resistance to plasma induced damage.

### Example 1. Synthesis of 1,4-bis(dimethylsiloxy)cyclohexane

To 0.77 g (5.78 mmol) of 1,1,3,3-tetramethyldisilazane was added 0.67 g (5.78 mmol) of 1,4-cyclohexanediol directly. After 16 hours, GC-MS showed product with the following peaks: m/z=232 (M+), 217 (M−15), 207, 189, 175, 149, 133, 117, 102, 87, 75, 59, 45.

### Example 2. Synthesis of 1,2-bis(dimethylsiloxy)cyclohexane

To 0.77 g (5.78 mmol) of 1,1,3,3-tetramethyldisilazane was added 0.67 g (5.78 mmol) of 1,2-cyclohexanediol directly. After 16 hours, GC-MS showed product with the following peaks: m/z=232 (M+), 217 (M−15), 207, 189, 173, 149, 133, 113, 101, 85, 75, 59, 41.

### Example 3: Deposition of Dense Organosilica Films from 1,4-bis(dimethylsiloxy)cyclohexane

Various dense organosilica films can be deposited on a 200 mm wafer using processing conditions similar to DEMS low k dielectric film deposition. 1,4-bis(dimethylsiloxy)cyclohexane precursor is delivered to the reaction chamber via direct liquid injection (DLI) at a flow rate of 100-2000 mg/min using 100-1000 standard cubic centimeters per minute (sccm) He carrier gas flow, O₂ at low flow rates of 10-50 mg/min or high flow rates of 100-1000 mg/min with a pedestal spacing of 350 mils. Films were grown at various temperatures of 300-400° C. over a pressure range of 2-9 Torr as summarized in Table 2.

TABLE 2
Deposition conditions for 1,4-bis(dimethylsiloxy)cyclohexane

| Power | Pressure | Temp. | Precursor flow | He carrier | O₂ flow | Dep time |
|---|---|---|---|---|---|---|
| (W) | (Torr) | (° C.) | (mg/min) | (sccm) | (mg/min) | (sec) |
| 500 | 9 | 300 | 500 | 100 | 10 | 60 |

Films grown according to the deposition conditions listed here from 1,4-bis(dimethylsiloxy)cyclohexane were compared to films derived from DEMS under the same process conditions. Films derived from 1,4-bis(dimethylsiloxy)cyclohexane were observed to have similar refractive index values, while the k value of the 1,4-bis(dimethylsiloxy)cyclohexane based organosilica films were substantially lower than the DEMS derived films: 2.76 and 3.1 as shown in Table 3, respectively. The results in Table 3 also demonstrate the deposition rate for 1,4-bis(dimethylsiloxy)cyclohexane is much higher than DEMS under similar conditions. FTIR analysis produced a spectrum with peaks consistent with film composition comprising carbon, silicon, and oxygen. Peaks at 1274 cm⁻¹ and ˜2960 cm⁻¹ correspond to —CH₃ bending and stretching bond vibrations. The film is predominantly composed of SiOₓ character, which is observed in the Si—O—Si network band at 1250 cm⁻¹ to 920 cm⁻¹ and the Si—O—Si cage bond vibrational modes as the shoulder peak at 1250 cm⁻¹.

TABLE 3
Comparison of dense organosilica films using
DEMS vs 1,4-bis(dimethylsiloxy)cyclohexane

| | DEMS | 1,4-bis(dimethylsiloxy)cyclohexane |
|---|---|---|
| k | 3.1 | 2.76 |
| Dep. Rate | 108 nm/min | 279.8 nm/min |
| RI | 1.43 | 1.42 |

### Example 4: Deposition of SiOC Film with O₂Flow Rates of 100 and 750 mg/Min for Lowering Carbon Incorporation

In addition, when the process was repeated using a higher O₂ flow rate of 100 and 750 mg/min, the resulting films were found to have lower carbon incorporation. FTIR spectra for films grown with varying O₂ flow rates and all other process parameters held constant show the amount of Oz introduced into the reaction chamber significantly alters the carbon concentration in the film as well as the k value, deposition rates, and refractive index. Adjusting O₂ flow can be used for optimizing the composition, growth rate, and physical properties of 1,4-bis(dimethylelloxy)cyclohexane derived films.

TABLE 4
Dense organosilica films using bis(dimethylsiloxy)cyclohexane
with higher O₂ flow rates

| | 100 mg/min O₂ flow | 750 mg/min O₂ flow |
|---|---|---|
| k | 3.64 | 4.18 |
| Dep. Rate | 657 nm/min | 217 nm/min |
| RI | 1.42 | 1.44 |

The invention claimed is:

1. A method for making a dense organosilica film with improved mechanical properties, the method comprising:
providing a substrate within a reaction chamber; introducing into the reaction chamber a gaseous composition comprising at least one alkoxysilane compound having the structure of given Formula I: 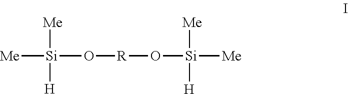
where R is an organic moiety derived from the group consisting of a linear or branched C₂ to C₅ alkane, a linear or branched C₂ to C₅ alkene, a linear or branched C₂ to C₅ alkyne, a C₄ to C₁₀ cyclic alkane, a C₄ to C₁₀ cyclic alkene, a C₅ to C₁₀ arene; and
applying energy to the gaseous composition comprising the at least one alkoxysilane in the reaction chamber to induce reaction of the gaseous composition comprising the at least one alkoxysilane to deposit an organosilica film on the substrate, wherein the organosilica film has a dielectric constant of from ˜2.40 to ˜3.20 and an elastic modulus of from ˜6 to ˜30 GPa.

2. The method of claim 1 wherein the at least one alkoxysilane comprises at least one selected from the group consisting of 2,3-bis(dimethylsiloxy) butane, 1,4-bis(dimethylsiloxy)cyclohexane, 1,2-bis(dimethylsiloxy)cyclohexane, 1,4-bis(dimethylsiloxy)-cis-2-butene, 1,4-bis(dimethylsiloxy)-2-butyne, 1,4-bis(dimethylsiloxy)benzene, 1,4-bis(dimethylsiloxymethyl)cyclohexane, 1,3-bis(dimethylsiloxy) propane, 1,3-bis(dimethylsiloxy)-2-methylpropane, 1,2-bis(dimethylsiloxy) propane, 1,3-bis(dimethylsiloxy) butane, 1,4-bis(dimethylsilyl) butane.

3. The method of claim 1 wherein the gaseous composition comprising the alkoxysilane is free of a hardening additive.

4. The method of claim 1 which is a chemical vapor deposition method.

5. The method of claim 1 which is a plasma-enhanced chemical vapor deposition method.

6. The method of claim 1 wherein the gaseous composition comprising the alkoxysilane further comprises the at least one oxidant selected from the group consisting of water vapor, water plasma, ozone, oxygen, oxygen plasma, oxygen/helium plasma, oxygen/argon plasma, nitrogen oxides plasma, carbon dioxide plasma, hydrogen peroxide, organic peroxides, and mixtures thereof.

7. The method of claim 1 wherein the gaseous composition comprising the alkoxysilane does not comprise an oxidant.

8. The method of claim 1 wherein the reaction chamber in the applying step comprises at least one gas selected from the group consisting of He, Ar, N₂, Kr, Xe, CO₂, and CO.

9. The method of claim 1 wherein the organosilica film has a refractive index (RI) of from ˜1.3 to ˜1.6 at 632 nm and carbon content as measured by XPS of from ˜10 at. % to ˜45 at. %.

10. The method of claim 1 wherein the organosilica film is deposited at a rate of from ˜5 nm/min to ˜2000 nm/min.

11. The method of claim 1 wherein the organosilica film has a relative disilylmethylene density from ˜10 to ˜30.

12. A composition for a vapor deposition of a dielectric film, the composition comprising at least one alkoxysilane compound having the structure of Formula I: 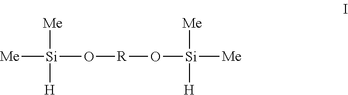
where R is an organic moiety derived from the group consisting of a linear or branched C₂ to C₅ alkane, a linear or branched C₂ to C₅ alkene, a linear or branched C₂ to C₅ alkyne, a C₄ to C₁₀ cyclic alkane, a C₄ to C₁₀ cyclic alkene, a C₅ to C₁₀ arene and wherein the alkoxysilane is substantially free of one or more impurities selected from the group consisting of a halide, water, nitrogen-containing impurities, oxygen-containing impurities and metals.

13. The composition of claim 12 wherein the at least one alkoxysilane comprises at least one selected from the group consisting of 2,3-bis(dimethylsiloxy) butane, 1,4-bis(dimethylsiloxy)cyclohexane, 1,2-bis(dimethylsiloxy)cyclohexane, 1,4-bis(dimethylsiloxy)-cis-2-butene, 1,4-bis(dimethylsiloxy)-2-butyne, 1,4-bis(dimethylsiloxy)benzene, 1,4-bis(dimethylsiloxymethyl)cyclohexane, 1,3-bis(dimethylsiloxy) propane, 1,3-bis(dimethylsiloxy)-2-methylpropane, 1,2-bis(dimethylsiloxy) propane, 1,3-bis(dimethylsiloxy) butane, 1,4-bis(dimethylsilyl) butane.

14. The composition of claim 12, wherein the halides comprise chloride ions.

15. The composition of claim 14, wherein the chloride ions, if present, are present at a concentration of 50 ppm or less as measured by IC.

16. The composition of claim 15, wherein the chloride ions, if present, are present at a concentration of 5 ppm or less as measured by IC.

17. The composition of claim 12, the alkoxysilane compound is substantially free of nitrogen-containing impurities.

18. The composition of claim 17, wherein the nitrogen-containing species, if present, are present at a concentration of 1000 ppm or less as measured by GC

19. The method of claim 6, further comprising tuning the carbon content in the resulting film by adjusting a flow rate of the oxidant.

20. A composition comprising at least one alkoxysilane compound having the structure of Formula I: 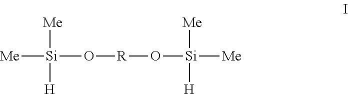
wherein R is an organic moiety derived from the group consisting of a linear or branched C₂ to C₅ alkane, a linear or branched C₂ to C₅ alkene, a linear or branched C₂ to C₅ alkyne, a C₄ to C₁₀ cyclic alkane, a C₄ to C₁₀ cyclic alkene, and a C₅ to C₁₀ arene.
